(19) United States
(12) Patent Application Publication
(10) Pub. No.: US 2018/0212618 A1
(43) Pub. Date: Jul. 26, 2018

(54) CIRCUITS AND METHODS FOR EXCESS LOOP DELAY COMPENSATIN IN DELTA-SIGMA MODULATORS

(71) Applicant: MediaTek Inc., Hsin-Chu (TW)

(72) Inventors: Tao He, Corvallis, OR (US); Michael A. Ashburn, JR., Groton, MA (US)

(21) Appl. No.: 15/875,931

(22) Filed: Jan. 19, 2018

Related U.S. Application Data
(60) Provisional application No. 62/556,717, filed on Sep. 11, 2017.
(60) Provisional application No. 62/448,418, filed on Jan. 20, 2017.

(51) Int. Cl. H03M 3/00

(52) U.S. Cl. CPC H03M 3/37; H03M 3/466; H03M 3/422

(57) ABSTRACT

Circuits for compensating delta-sigma modulators for excess loop delay are described. These circuits may be coupled to quantizers, and may configured to select the threshold values supplied to the quantizers for comparison with an analog signal. The threshold values may each be selected from a corresponding plurality of reference values, and may be set such that the numerical order of threshold values varies over time. For example, the threshold value provided to a first comparator of the quantizer may be greater than the threshold value provided to a second comparator of the quantizer in a first time interval, but the opposite scenario may occur in a second time interval. The circuits may include multiplexers for selecting the threshold values, thermometric encoders, reference selectors and reference multiplexers.

### RELATED APPLICATIONS

This Application claims priority under 35 U.S.C. § 119(e) to U.S. Provisional Application Ser. No. 62/448,418, entitled “DIGITAL EXCESS LOOP DELAY COMPENSATION WITH HARDWARE REDUCTION” filed on Jan. 20, 2017, which is herein incorporated by reference in its entirety and claims priority under 35 U.S.C. § 119(e) to U.S. Provisional Application Ser. No. 62/556,717, entitled “ DIGITAL EXCESS LOOP DELAY COMPENSATION ” filed on Sep. 11, 2017, which is herein incorporated by reference in its entirety

### TECHNICAL FIELD

The present application relates to delta-sigma analog-to-digital converters.

### BACKGROUND

Delta-sigma analog-to-digital converters (ADC) use integrators and feedback loops to filter noise in the low frequencies, so as to enhance signal-to-noise ratio. Some delta-sigma ADCs include 1-bit digital-to-analog converters (DAC) in the feedback loop. Other delta-sigma ADCs include multi-bit DACs. ADCs with multi-bit DACs typically provide higher digitization resolutions.

### BRIEF SUMMARY

Some embodiments are directed to a method comprising converting an analog input signal into a digital output at least in part by: filtering the analog input signal with a filter, generating the digital output by comparing, with a plurality of comparators, the filtered analog input signal to a plurality of threshold values, selecting, based on a previous output of the plurality of comparators, at least one of the plurality of threshold values from a plurality of corresponding reference values, wherein selecting at least one of the plurality of threshold values comprises varying a numerical order of the plurality of threshold values over time, and providing the digital output to an input port of the filter through a DAC.

Some embodiments are directed to a delta-sigma modulator comprising a filter, a quantizer comprising a plurality of comparators, each of the plurality of comparators being configured to compare an output of the filter to a respective threshold value, at least one of the respective threshold values being selected from a plurality of corresponding reference values, a control circuit coupled to the quantizer and configured to vary over time, based on a previous output of the quantizer, a numerical order of the respective threshold values, and a feedback loop coupling the quantizer to an input port of the filter.

Some embodiments are directed to a delta-sigma modulator comprising: a filter, a quantizer comprising at least a first, second and third comparators, a multiplexer comprising at least a first, second and third 2-to-1 multiplexers, an output of the first 2-to-1 multiplexer being coupled to the first comparator, an output of the second 2-to-1 multiplexer being coupled to the second comparator and an output of the third 2-to-1 multiplexer being coupled to the third comparator, a control circuit configured to select: a first threshold value between a first and a fourth reference value using the first 2-to-1 multiplexer, a second threshold value between a second and a fifth reference value using the second 2-to-1 multiplexer, and a third threshold value between a third and a sixth reference value using the third 2-to-1 multiplexer, such that a numerical order of the first, second and third threshold values varies over time, and a feedback loop coupling the quantizer to an input port of the filter.

The foregoing summary is provided by way of illustration and is not intended to be limiting.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing.

FIG. 1 is a block diagram illustrating a delta-sigma modulator, in accordance with some non-limiting embodiments.

FIG. 2A is a block diagram illustrating a representative digitizer that may be used in the delta-sigma modulator of FIG. 1, in accordance with some non-limiting embodiments.

FIG. 2B is a chart illustrating an example of how threshold values may be selected over time in the digitizer of FIG. 2A, in accordance with some non-limiting embodiments.

FIG. 3 is a block diagram illustrating a representative driver that may be used in the digitizer of FIG. 2A, in accordance with some non-limiting embodiments.

FIG. 4 is a block diagram illustrating a representative reference selector that may be used in the driver of FIG. 3, in accordance with some non-limiting embodiments.

FIG. 5 is a flowchart illustrating a representative method for converting an analog input signal into a digital output, in accordance with some embodiments.

FIG. 6 is a plot illustrating an example of an analog input signal that may be digitized using the digitizer of FIG. 2A, in accordance with some non-limiting embodiments.

FIGS. 7A-7E are tables illustrating an example of how the digitizer of FIG. 2A responds to the analog input signal of FIG. 6, in accordance with some non-limiting embodiments.

### DETAILED DESCRIPTION

The inventors have recognized and appreciated that conventional circuits for compensating delta-sigma modulators for excess loop delay are either very slow or very costly. “Excess loop delay” is a term used in the art for referring to the delay accumulation arising in the delta-sigma modulator's loop. This delay may cause detrimental effects to the performance and stability of sigma-delta modulator. Certain excess loop delay compensating circuits are not sufficiently fast to be able to digitize analog signals with modulation speeds above 1 GHz, which is often the case in sensing and communication applications. On the other hand, other excess loop delay compensating circuits can handle such high-speed signals, but their implementations require large areas on the integrated circuit in which the delta-sigma modulator is disposed, thus significantly increasing the cost of the overall modulator. Some of the circuits, for example, include a large number of multiplexers and/or a large number of conductive lines in the quantizer, which can increase the size of the modulator's die, and consequently, its costs.

Recognizing these limitations in the prior art, the inventors have developed high-speed, compact circuits for compensating delta-sigma modulators for excess loop delay. Unlike conventional circuits, the circuits developed by the inventors can be employed in applications calling for large modulation speeds (though, of course, they may also be used in lower speed applications) and can limit the amount of space used on the die.

In some embodiments, the reduction in space utilization may be accomplished by reducing the number of multiplexers and control lines used for driving the operations of the modulator's quantizer. This reduction in the number of multiplexers and lines, in turn, may be accomplished by varying the numerical order of the thresholds provided to the quantizer, which can significantly simplify the design of the control circuits.

Using these control circuits, an analog input signal may be digitized by 1) filtering the signal, for example using an integrator or other types of low-pass filters, 2) comparing the filtered signal to a plurality of threshold values with a plurality of comparators, 3) selecting, based on a previous output of the plurality of comparators, each of the plurality of threshold values from a plurality of corresponding reference values, wherein selecting each of the plurality of threshold values comprises varying the numerical order of the plurality of threshold values over time, and 4) providing the digital output to an input port of the filter through a feedback loop.

In varying the numerical order of the threshold values, the threshold value provided to a first comparator may be greater than the threshold value provided to a second comparator in a first time interval, but the opposite scenario may occur in a second time interval.

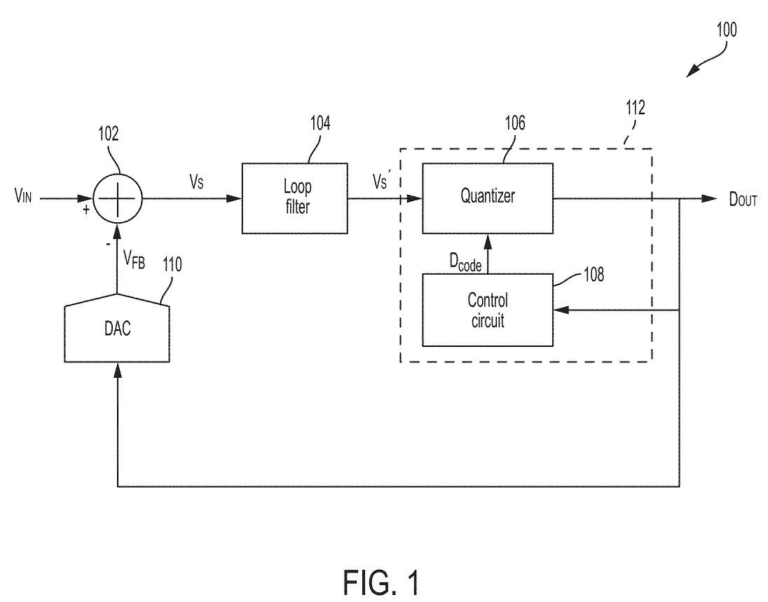

FIG. 1 is a block diagram illustrating a delta-sigma modulator, according to an embodiment of the present application. The delta-sigma modulator 100 may include a signal subtraction circuit 102, a loop filter 104, a quantizer 106, a control circuit 108, and a digital-to-analog converter (DAC) 110. The signal subtraction circuit 102 may be an adder (which may be implemented using a differential amplifier to perform analog signal subtraction). The signal subtraction circuit 102 may be arranged to subtract an analog feedback signal V_{FB} from an analog input signal V_{IN} to generate a difference signal V_{S}. The loop filter 104 may include one or more integrators, resonators or other types of filters, including low-pass filters. The loop filter 104 may be arranged to perform a filtering operation upon the difference signal V_{S} to generate a filtered signal V_{S}'. In some embodiments, loop filter 104 may be arranged such that the spectral density of the noise arising in the delta-sigma modulator is low at the low frequencies, thus providing a spectral region in which analog signals can be digitized with minimal noise.

Quantizer 106 and control circuit 108 collectively form a digitizer 112. The quantizer 106 may be controlled by the control circuit 108, and may be arranged to quantize (e.g., digitize) the filtered signal V_{S}' into a digital output signal D_{OUT}. The DAC 110 may be located in a feedback path between an output of the quantizer 106 and an input of the signal subtraction circuit 102, and arranged to perform a digital-to-analog conversion operation based on the digital output signal D_{OUT}. The output of the DAC 110, feedback signal V_{FB}, may be combined with analog input signal V_{IN} using signal subtraction circuit 102.

The delay accumulated by a signal traveling through quantizer 106, DAC 110 and/or other parasitic components present along the feedback path is referred to as excess loop delay. Excess loop delay may give rise to a non-zero delay between the quantizer clock edge and the edge of the DAC pulse. Ideally, DAC pulses should respond immediately to the quantizer clock edges, but due to non-zero gate delays and transistor switching time, there may be a finite delay in the feedback loop. The timing errors may be accumulated over time through the DAC, which may cause detrimental effects on the performance and stability of the delta-sigma modulator.

Excess loop delay may be compensated at least in some embodiments by adding a local feedback loop around the quantizer. As shown in FIG. 1, control circuit 108 may be arranged to form a closed loop with the quantizer 106. The gain of this local feedback may be arranged in a manner which compensates for excess loop delay.

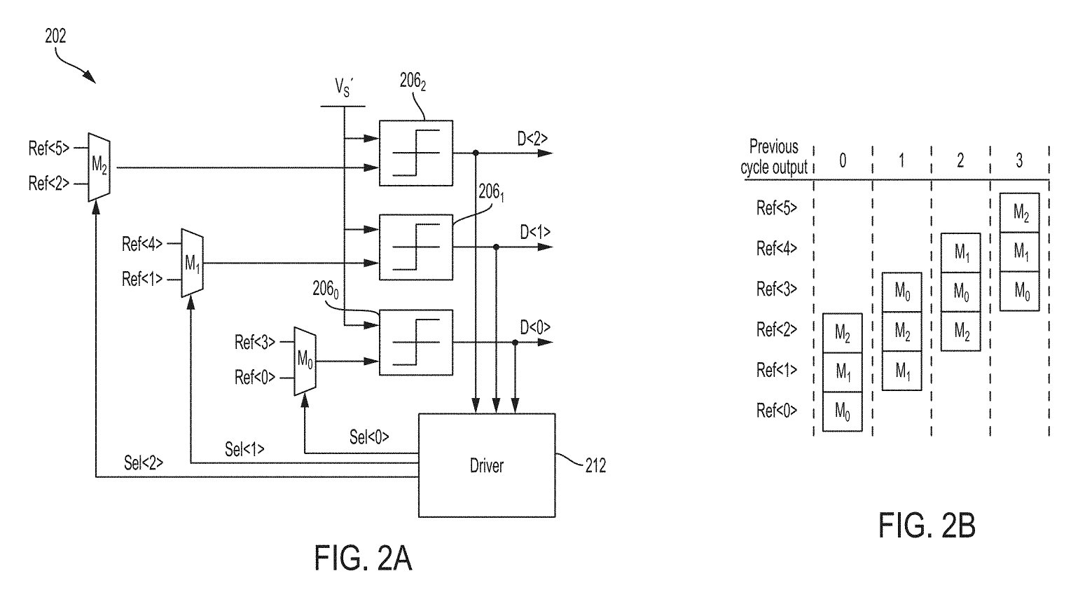

FIG. 2 is a block diagram illustrating an example of a digitizer that may be used in delta-sigma modulator 100, in accordance with some embodiments. As illustrated, digitizer 202 may comprise comparators 206₀, 206₁ and 206₂, multiplexers M₀, M₁ and M₂, and driver 212. While FIG. 2A illustrates a digitizer having three comparators and three multiplexers, thus producing three digital outputs, any other suitable number of comparators and multiplexers may be used in other embodiments. Comparators 206₀, 206₁ and 206₂ collectively form quantizer 106 (FIG. 1) while multiplexers M₀, M₁ and M₂ and driver 212 collectively form control circuit 108 (FIG. 1). Digital output D_{OUT} comprises outputs D<0>, D<1> and D<2> in this example, though outputs having more bits are also possible by increasing the number of comparators.

In this example, each comparator receives, as a first input, signal V_{S}' and, as a second input, the threshold value output from a respective multiplexer. The comparators are arranged to output values based on the comparison between its inputs. For example, the output of a comparator may be a 1 if V_{S}' is greater than the threshold and 0 if less than he threshold, though the opposite logic is also possible.

Each of the multiplexers M₀, M₁ and M₂ is configured to select one among its inputs. In this case, multiplexers M₀, M₁ and M₂ are 2-to-1 multiplexers. That is, each multiplexer selects as an output one between its two inputs. Each multiplexer receives a control signal “Sel” for selecting one of its inputs. As shown in FIG. 2A, control signal Sel<0> may control M₀, control signal Sel<1> may control M₁ and control signal Sel<2> may control M₂. In this example, each Sel signal includes one bit for selecting one between two inputs of a multiplexer. The Sel signals are output by driver 212 based on a previous output D_{OUT} (i.e., D<0>, D<1> and D<2>) of the comparators, such as the output at the previous clock cycle.

In this case, multiplexer M₀ receives, as inputs, reference values Ref<0> and Ref<3>, multiplexer M₁ receives reference values Ref<1> and Ref<4>, and multiplexer M₂ receives reference values Ref<2> and Ref<5>. In some embodiments, Ref<5> is greater than Ref<4>, which is greater than Ref<3>, which is greater than Ref<2>, which is greater than Ref<1>, which is greater than Ref<0>, though of course other configurations are also possible. In one illustrative embodiments, Ref<0>=0, Ref<1>=1V, Ref<2>=2V, Ref<3>=3V, Ref<4>=4V and Ref<5>=5V.

The inventors have appreciated that the number of lines and components (e.g., multiplexers) needed to implement driver 212 may be limited by utilizing a control scheme whereby the numerical order of the threshold values provided as inputs to the comparators is varied over time. For example, at time t₁ the threshold values may be arranged according to a first numerical order in which the threshold value of multiplexer M₂ is greater than the threshold value of multiplexer M₁, which is greater than the threshold value of multiplexer M₀. This numerical order, however, may be varied at time t₂, when the threshold value of multiplexer M₀ is set to be greater than the threshold value of multiplexer M₂ Varying the numerical order of the threshold values increases the number of combinations of thresholds than can be achieved for a given number of multiplexers. In other words, if the numerical order of the threshold values was not allowed to vary as described herein, the number of multiplexers needed to achieve the same number of combination of thresholds would be significantly greater.

FIG. 2B illustrates the operations of the digitizer of FIG. 2A, according to one specific example. In the chart, each column header 0, 1, 2 and 3 represents the sum of the digital outputs, D<2>, D<1> and D<0>, from the previous cycle. This sum is used to determine the multiplexer outputs M₀, M₁ and M₂ for the current cycle. For example, when the previous sum is 0, multiplexer M₀ selects Ref<0>, multiplexer M₁ selects Ref<1>, and multiplexer M₂ selects Ref<2>. Hence, the numerical order is such that the threshold value of multiplexer M₂ is greater than the threshold value of multiplexer M₁, which is greater than the threshold value of multiplexer M₀.

When the previous sum is 1, multiplexer M₀ selects Ref<3>, multiplexer M₁ selects Ref<1>, and multiplexer M₂ selects Ref<2>. As a result, the new numerical order is such that the threshold value of multiplexer M₀ is greater than the threshold value of multiplexer M₂, which is greater than the threshold value of multiplexer M₁.

When the previous sum is 2, multiplexer M₀ selects Ref<3>, multiplexer M₁ selects Ref<4>, and multiplexer M₂ selects Ref<2>. As a result, the new numerical order is such that the threshold value of multiplexer M₁ is greater than the threshold value of multiplexer M₀, which is greater than the threshold value of multiplexer M₂.

When the previous sum is 3, multiplexer M₀ selects Ref<3>, multiplexer M₁ selects Ref<4>, and multiplexer M₂ selects Ref<5>. As a result, the same numerical order as in the initial case is established. The specific manner in which the numerical order of the threshold values is varied over time may depend on the previous digital output of digitizer 202 (the value of V_{S}' relative to the values of the references). In one embodiment, a portion of the comparators may have fixed thresholds while other comparators may have adjustable thresholds.

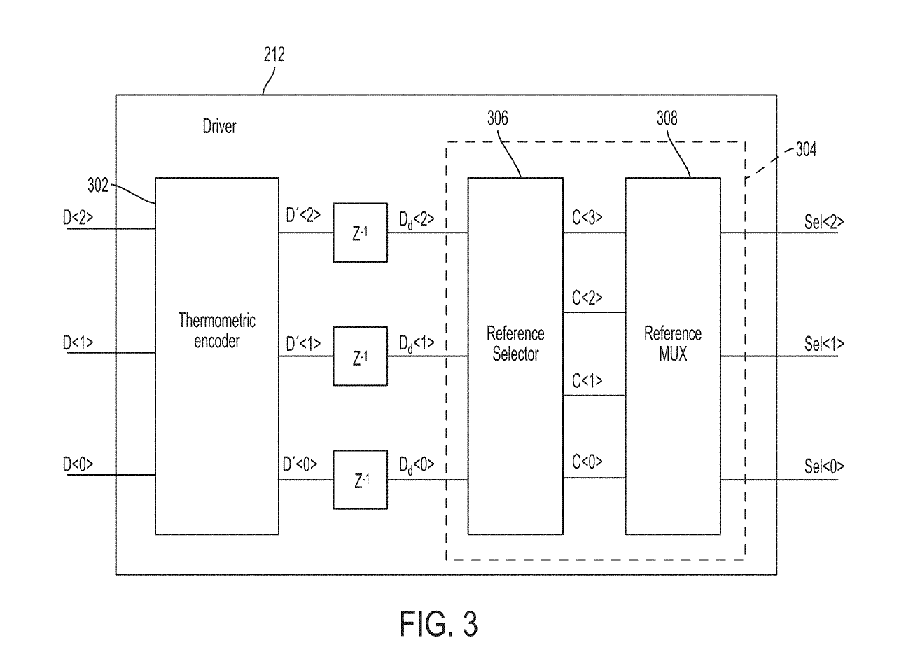

One specific implementation for driver 212 is illustrated in FIG. 3, according to some non-limiting embodiments. In this case, driver 212 includes a thermometric encoder 302, a plurality of delay units (labeled Z⁻¹), a reference selector 306 and a reference multiplexer (MUX) 308. Driver 212 outputs control signals Sel<0>, Sel<1> and Sel<2> for selecting the new thresholds based on the previous digital outputs D<0>, D<1> and D<2>.

Thermometric encoder 302 is configured to receive digital outputs D<0>, D<1> and D<2> and to convert these outputs based on a thermometric code. For example, the outputs D can assume one of the following values (depending on the output of the comparators): 000, 001, 011, 111 (where the least significant bit corresponds to D′<0>and the most significant bit corresponds to D′<2>). The specific thermometric code at the output of the encoder may depend on the number of 1s present in the output of the comparators. For example, if the comparators' output does not include any 1, the output of the encoder may be 000; if the comparators' output includes a single 1, the output of the encoder may be 001; if the comparators' output includes two 1s, the output of the encoder may be 011; and if the comparators' output includes three ls, the output of the encoder may be 111.

In some embodiments, the outputs of the thermometric encoder may be delayed using delay units Z⁻¹. Such one cycle delay ensures that the threshold selection for the current clock period is based on the digital output of the previous period. Also, such delay relaxes the timing in the encoder 302, selector 306 and MUX 308. Delay units Z⁻¹ may be implemented using latches triggered by the clk_b, the opposite of clock signal clk (which triggers the rest of the digitizer 112). In this way, all the bits coming out of the encoder are re-synced after a half clock cycle. Therefore, comparators 206₀, 206₁, and 206₂, and encoder 302 have a half clock cycle to operate and Reference Selector 306 and MUX 308 have another half cycle to operate. The relaxed timing may save power dissipation in the digitizer 202. The outputs of the delay units D_{d}<0>, D_{d}<1> and D_{d}<2> may be provided to reference selector 306.

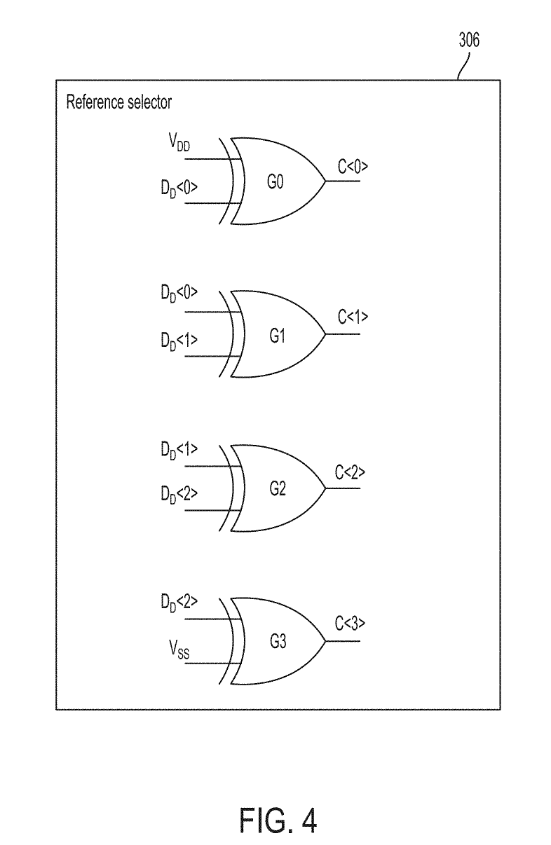

The use of a thermometric encoder as described above allows the circuitry of the reference selector 306 to be significantly simplified, thus substantially reducing the space occupied by the circuit, its complexity and power consumption. Reference selector 306, which selects the reference values for providing the thresholds to the comparators, may be implemented using the circuit of FIG. 4 in some embodiments. As shown, reference selector 306 is implemented in this case with a simple circuit having four XOR gates: G0, G1, G2 and G3. The output of the reference selector, in this case, may be one of the following: 0001, 0010, 0100 or 1000. Depending on which of these four output combinations is provided by the reference selector, one among four possible combinations of thresholds is selected (for example, one among the four combination illustrated in FIG. 2B). Referring back to FIG. 3, reference MUX 308 may provide the control signals Sel<0>, Sel<1> and Sel<2>, based on the output of the reference selector.

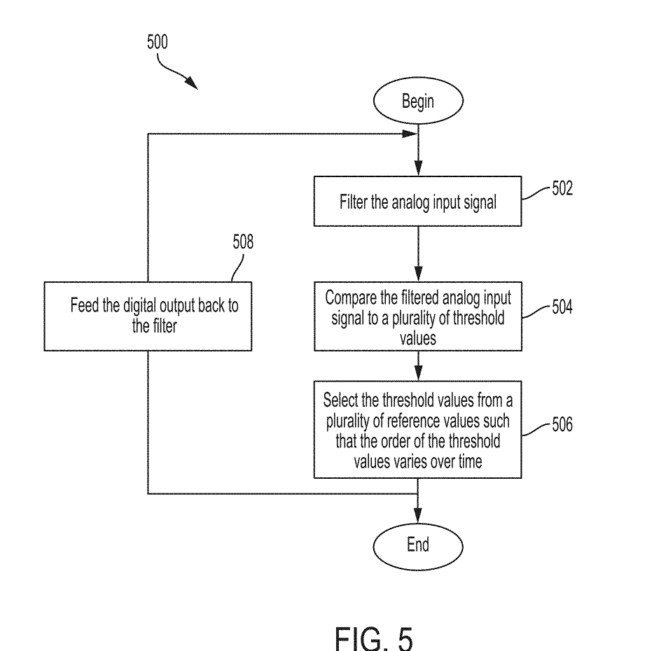

FIG. 5 is a flowchart illustrating a representative method for converting an analog input signal into a digital output while compensating for excess loop delay, in accordance with some embodiments. Method 500 begins at block 502, in which an analog input signal is filtered, for example using one or more integrators or other loop filters.

At block 504, a digital output may be generated by comparing, using a quantizer having a plurality of comparators, the filtered signal to a plurality of threshold values.

At block 506, each of the plurality of threshold values is selected from a plurality of corresponding reference values based on a previous output of the plurality of comparators. In some circumstances, selecting the threshold values may cause a variation in the numerical order of the threshold values relative to a previous iteration. For example, initially the numerical order may be such that the threshold value of the first comparator is greater than the threshold value of the second comparator, which is greater than the threshold value of the third comparator. Subsequently, the threshold value of the third comparator may be toggled. As a result, the new numerical order may be such that the threshold value of the third comparator is greater than the threshold value of the first comparator, which is greater than the threshold value of the second comparator.

At block 508, the output of the comparators may be provided to an input of the filter used in block 502. For example, the output may be converted to the analog domain, combined with (e.g., subtracted from) the analog input signal, and the combined analog signal may be provided to an input of the filter.

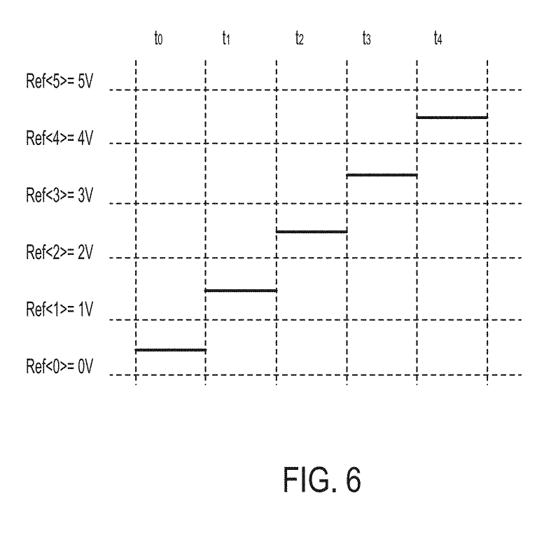

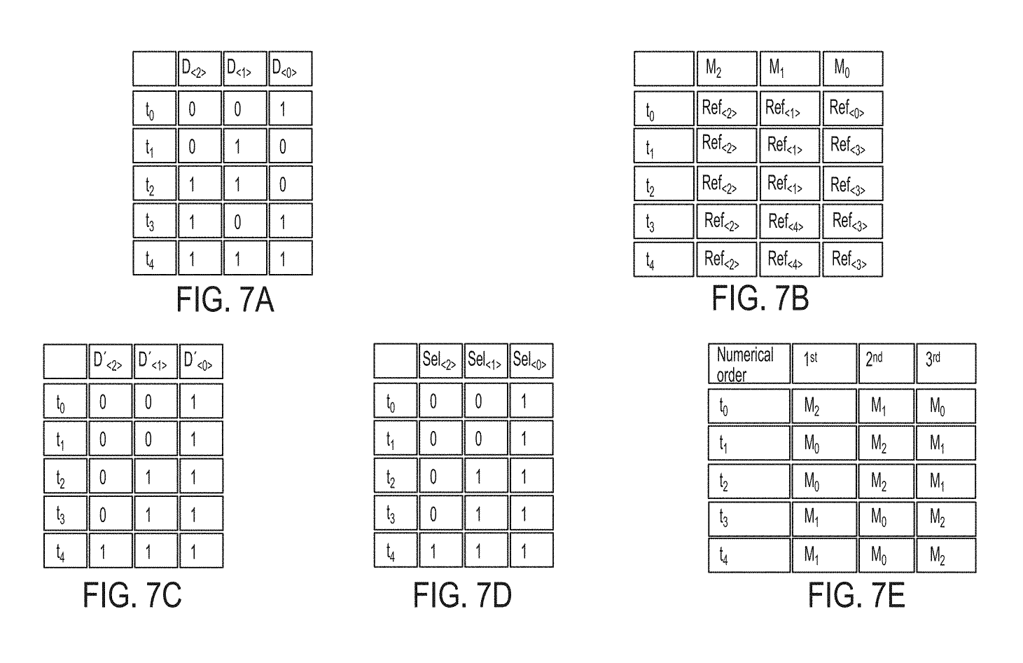

FIGS. 6 and 7A-7D provide an example illustrating how the digitizer of FIG. 2A may be operated, at least in some embodiments. In particular, FIG. 6 is a chart showing an example of a filtered analog input signal. In this example, the filtered analog input signal is equal to 0.5V during time interval t₀, 1.5V during time interval t₁, 2.5V during time interval t₂, 3.5V during time interval t₃, and 4.5V during time interval t₄. As further illustrated in FIG. 6, in this case Ref<0>=0, Ref<1>=1V, Ref<2>=2V, Ref<3>=3V, Ref<4>=4V and Ref<5>=5V.

FIG. 7A-7D are tables illustrating how D<0>, D<1> and D<2> (FIG. 7A), the outputs of multiplexers M₀, M₁ and M₂ (FIG. 7B), D′<0>, D′<1> and D′<2> (FIG. 7C) and Sel<0>, Sel<1> and Sel<2> (FIG. 7D) vary over time from t₀ through t₄, in response to the analog signal of FIG. 6. FIG. 7E illustrates the numerical order of the threshold values output by multiplexers M₀, M₁ and M₂ over time from t₀ through t₄.

Initially, at t=t₀, the thresholds of multiplexers M₀, M₁ and M₂ are set to Ref<0>, Ref<1> and Ref<2>, respectively. Therefore, the numerical order of the thresholds is such that the output of multiplexer M₂ (1^{st} position in FIG. 7E) is greater than the output of multiplexer M₁ (2^{nd} position), which is greater than the output of multiplexer M₀ (3^{rd} position). As a result, D<0>=1, being the analog signal (0.5V) greater than Ref<0> (0V), while D<1>=D<2>=0, being the analog signal less that Ref<1> (1V) and Ref<2> (2V).

Since the output of the comparators includes a single 1, the output of the thermometric encoder (D′<2>, D′<1> and D′<0>) is 001. This results is a Sel signal equal to 001, which causes multiplexer M₀ to toggle to Ref<3> at the following cycle. In this case, the new numerical order of the thresholds is such that the output of multiplexer M₀ (1^{st} position) is greater than the output of multiplexer M₂ (2^{nd} position), which is greater than the output of multiplexer M₁ (3^{rd} positon).

At time t₁, the analog signal rises to 1.5V. As a result, D<0>=0 being the analog signal less than Ref<3> (3V), D<1>=1 being the analog signal greater than Ref<1> (1V), D<2>=0 being the analog signal less that Ref<2> (2V). Nothing changes in D′<2>, D′<1> and D′<0> and Sel<2>, Sel<1> and Sel<0>, and consequently, in the numerical order of the thresholds.

At time t₂, the analog signal rises to 2.5V. As a result, D<2> toggles to 1 being the analog signal greater than Ref<2> (2V), which causes D′<0> and Sel<1> to toggle to 1. This, in turn, cause multiplexer M₁ to toggle to Ref<4> at the following cycle. In this case, the numerical order of the thresholds is such that the output of multiplexer M₁ (1^{st} position) is greater than the output of multiplexer M₀ (2^{nd} position), which is greater than the output of multiplexer M₂ (3^{rd} positon).

At time t₃, the analog signal rises to 3.5V. As a result, D<1>=1 being the analog signal greater than Ref<3> (3V), D<1>=0 being the analog signal less than Ref<4> (4V), D<2>=1 being the analog signal greater that Ref<2> (2V). Since the number of 1s in the output is still two, nothing changes in D′<2>, D′<1> and D′<0> and Sel<2>, Sel<1> and Sel<0>.

At time t₄, the analog signal rises to 4.5V. As a result, D<1>=1 being the analog signal greater than Ref<3> (3V), D<1>=1 being the analog signal greater than Ref<4> (4V), D<2>=1 being the analog signal greater that Ref<2> (2V).

Various aspects of the apparatus and techniques described herein may be used alone, in combination, or in a variety of arrangements not specifically discussed in the embodiments described in the foregoing description and is therefore not limited in its application to the details and arrangement of components set forth in the foregoing description or illustrated in the drawings. For example, aspects described in one embodiment may be combined in any manner with aspects described in other embodiments. In one embodiment, a portion of the comparators may have fixed thresholds while other comparators may have adjustable thresholds.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including”, “comprising”, “having”, “containing” or “involving” and variations thereof herein, is meant to encompass the items listed thereafter and equivalents thereof as well as additional items.

The use of “coupled” or “connected” is meant to refer to circuit elements, or signals, that are either directly linked to one another or through intermediate components.

What is claimed is:

1. A method comprising:
converting an analog input signal into a digital output at least in part by:
filtering the analog input signal with a filter;
generating the digital output by comparing, with a plurality of comparators, the filtered analog input signal to a plurality of threshold values;
selecting, based on a previous output of the plurality of comparators, at least one of the plurality of threshold values from a plurality of corresponding reference values, wherein selecting at least one of the plurality of threshold values comprises varying a numerical order of the plurality of threshold values over time; and
providing the digital output to an input port of the filter.

2. The method of claim 1, wherein the plurality of threshold values comprise at least a first and second threshold values, and wherein:
varying an order of the plurality of threshold value comprises setting the plurality of threshold values such that the first threshold value is greater than the second threshold value in a first time interval and the second threshold value is greater than the first threshold value in a second time interval.

3. The method of claim 2, wherein the first threshold value is selectable from one between a first reference value and a third reference value, and second threshold value is selectable from one between a second reference value and a fourth reference value, wherein the second reference value is greater than the first reference value and is less than the third reference value.

4. The method of claim 1, further comprising delaying the digital output by half a clock cycle.

5. The method of claim 1, further comprising encoding the digital output using a thermometric encoder, and using the encoded digital output to select at least one of the plurality of threshold values.

6. The method of claim 1, wherein selecting at least one of the plurality of threshold values from a plurality of corresponding reference values comprises selecting an output of at least one of a plurality of 2-to-1 multiplexers.

7. The method of claim 1, wherein providing the digital output to an input of the filter comprises converting the digital output into an analog signal.

8. A delta-sigma modulator comprising:
a filter;
a quantizer comprising a plurality of comparators, each of the plurality of comparators being configured to compare an output of the filter to a respective threshold value, at least one of the respective threshold values being selected from a plurality of corresponding reference values;
a control circuit coupled to the quantizer and configured to vary over time, based on a previous output of the quantizer, a numerical order of the respective threshold values; and
a feedback loop coupling the quantizer to an input port of the filter.

9. The delta-sigma modulator of claim 8, wherein the respective threshold values comprise at least a first and second threshold values, and wherein the control circuit is further configured to:
vary an order of the respective threshold values by setting the respective threshold values such that the first threshold value is greater than the second threshold value in a first time interval and the second threshold value is greater than the first threshold value in a second time interval.

10. The delta-sigma modulator of claim 9, wherein the first threshold value is selectable from one between a first reference value and a third reference value, and second threshold value is selectable from one between a second reference value and a fourth reference value, wherein the second reference value is greater than the first reference value and is less than the third reference value.

11. The delta-sigma modulator of claim 8, further comprising an encoder configured to receive an output of the quantizer and to encode the output of the quantizer according to a thermometric code.

12. The delta-sigma modulator of claim 11, further comprising a plurality of delay elements coupled to respective output ports of the encoder.

13. The delta-sigma modulator of claim 11, further comprising a reference selector coupled to the encoder, the reference selector comprising a plurality of XOR gates.

14. The delta-sigma modulator of claim 8, further comprising a plurality of multiplexers, at least one of the plurality of multiplexers being coupled to one of the respective comparators.

15. The delta-sigma modulator of claim 14, wherein at least one of the plurality of multiplexers is configured to output a threshold value selectable from between at least a first and second reference values.

16. The delta-sigma modulator of claim 14, wherein at least one of the plurality of multiplexers is a 2-to-1 multiplexer.

17. A delta-sigma modulator comprising:
a filter;
a quantizer comprising at least a first, second and third comparators;
a multiplexer comprising at least a first, second and third 2-to-1 multiplexers, an output of the first 2-to-1 multiplexer being coupled to the first comparator, an output of the second 2-to-1 multiplexer being coupled to the second comparator and an output of the third 2-to-1 multiplexer being coupled to the third comparator;
a control circuit configured to select:
a first threshold value between a first and a fourth reference value using the first 2-to-1 multiplexer,
a second threshold value between a second and a fifth reference value using the second 2-to-1 multiplexer, and
a third threshold value between a third and a sixth reference value using the third 2-to-1 multiplexer,
such that a numerical order of the first, second and third threshold values varies over time; and
a feedback loop coupling the quantizer to an input port of the filter.

18. The delta-sigma modulator of claim 17, wherein the third reference value is greater than the second reference value, which is greater than the first reference value, the second reference value being between the first reference value and the fifth reference value.

19. The delta-sigma modulator of claim 17, further comprising a first, second and third delay elements coupled to the quantizer.

20. The delta-sigma modulator of claim 17, further comprising an encoder configured to receive an output of the quantizer and to encode the output of the quantizer according to a thermometric code.
